(19) United States
(12) Patent Application Publication
(10) Pub. No.: US 2025/0091096 A1
(43) Pub. Date: Mar. 20, 2025

(54) CLEANING APPARATUS FOR A WIRE CLAMP CONFIGURED TO CLAMP A WIRE USED IN A WIRE BONDING PROCESS AND CLEANING SYSTEM INCLUDING THE CLEANING APPARATUS

(71) Applicant: SAMSUNG ELECTRONICS CO., LTD., SUWON-SI (KR)

(72) Inventor: Junsuk LIM, Suwon-si (KR)

(21) Appl. No.: 18/610,940

(22) Filed: Mar. 20, 2024

(30) Foreign Application Priority Data
Sep. 20, 2023 (KR) 10-2023-0125645

(51) Int. Cl. B08B 1/30; B08B 1/10; B24D 11/00; H01L 23/00

(52) U.S. Cl. CPC B08B 1/30; B08B 1/10; B24D 11/00; H01L 24/78; H01L 2224/7801

(57) ABSTRACT

A cleaning apparatus for a wire clamp includes: a cleaner that cleans the wire clamp that clamps a wire; a supplying roller that supplies a cleaning tape to the cleaner; a first guide roller that applies a tension to the cleaning tape that is supplied from the supplying roller to the cleaner; a collecting roller that collects the cleaning tape, which cleans the wire clamp, from the cleaner; and a second guide roller that applies a tension to the cleaning tape that is collected from the cleaner by the collecting roller.

### CROSS-REFERENCE TO RELATED APPLICATION

This application claims priority under 35 USC § 119 to Korean Patent Application No. 10-2023-0125645, filed on Sep. 20, 2023 in the Korean Intellectual Property Office (KIPO), the disclosure of which is incorporated by reference herein in its entirety.

### TECHNICAL FIELD

Example embodiments of the present inventive concept relate to a cleaning apparatus and a cleaning system for a wire clamp. More particularly, example embodiments of the present inventive concept relate to a cleaning apparatus for a wire clamp configured to clamp a wire used in a wire bonding process and a cleaning system including the cleaning apparatus.

### DISCUSSION OF THE RELATED ART

Generally, a wire bonding apparatus may be configured to electrically connect a package substrate with a semiconductor chip by using a conductive wire. Typically, the wire bonding apparatus may include a heater, a capillary, a wire clamp, etc. The heater may heat the package substrate. The capillary may draw the conductive wire toward the package substrate and the semiconductor chip. The wire clamp may clamp the wire.

The wire clamp, which directly contacts the wire, may be contaminated by a contaminant that is generated from the wire. The contaminant may cause an error for a semiconductor device. Thus, it may be desirable to periodically clean the wire clamp.

Typically, a cleaning apparatus may clean the wire clamp by using an abrasive. However, the abrasive might not completely remove the contaminant from the wire clamp.

### SUMMARY

According to example embodiments of the present inventive concept, a cleaning apparatus for a wire clamp includes: a cleaner that cleans the wire clamp that clamps a wire; a supplying roller that supplies a cleaning tape to the cleaner; a first guide roller that applies a tension to the cleaning tape that is supplied from the supplying roller to the cleaner; a collecting roller that collects the cleaning tape, which cleans the wire clamp, from the cleaner; and a second guide roller that applies a tension to the cleaning tape that is collected from the cleaner by the collecting roller.

According to example embodiments of the present inventive concept, a cleaning apparatus for a wire clamp includes: a cleaner configured to clean the wire clamp that clamps a wire; a supplying roller that supplies a cleaning tape to the cleaner; a collecting roller that collects the cleaning tape, which cleans the wire clamp, from the cleaner; and a wire guide that pushes the wire to release the wire from the wire clamp before cleaning the wire clamp with the cleaner.

According to example embodiments of the present inventive concept, a cleaning system for a wire clamp includes: a first cleaning apparatus that cleans the wire clamp, which clamps a wire, by using a first cleaning tape; and a second cleaning apparatus that cleans the wire clamp by using a second cleaning tape.

### BRIEF DESCRIPTION OF THE DRAWINGS

The above and other features of the present inventive concept will become more apparent by describing in detail example embodiments thereof, with reference to the accompanying drawings, in which:

FIG. 1 is a plan view illustrating a cleaning apparatus for a wire clamp in accordance with example embodiments of the present inventive concept;

FIGS. 2, 3 and 4 are plan views illustrating an operation of a wire guide in the cleaning apparatus in FIG. 1;

FIG. 5 is a plan view illustrating a cleaning system for a wire clamp in accordance with example embodiments of the present inventive concept;

FIG. 6 is a plan view illustrating a first cleaning apparatus of the cleaning system in FIG. 5;

FIG. 7 is a plan view illustrating a second cleaning apparatus of the cleaning system in FIG. 5; and

FIGS. 8, 9, 10, 11, 12, 13, 14 and 15 are plan views illustrating an operation of the cleaning system in FIG. 5.

### DETAILED DESCRIPTION OF THE EMBODIMENTS

Hereinafter, example embodiments of the present inventive concept will be explained in detail with reference to the accompanying drawings.

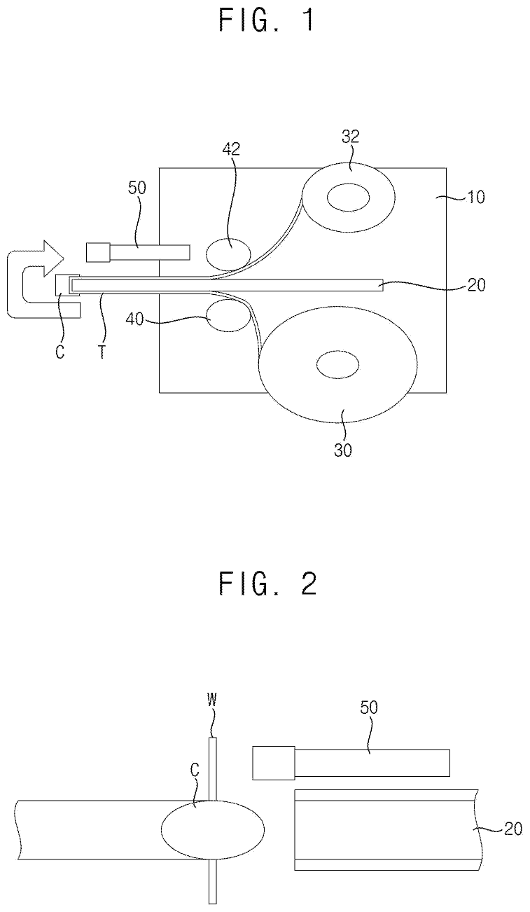

FIG. 1 is a plan view illustrating a cleaning apparatus for a wire clamp in accordance with example embodiments of the present inventive concept.

Referring to FIG. 1, a cleaning apparatus for a wire clamp in accordance with example embodiments of the present inventive concept may include a base 10, a cleaner 20, a supplying roller 30, a collecting roller 32, a first guide roller 40, a second guide roller 42 and a wire guide 50.

The wire clamp C may be arranged at a first side of the base 10. For example, the wire clamp C may be arranged at a left side of the base 10. The cleaner 20 may be movably arranged at a central portion of the base 10. For example, the cleaner 20 may move along a central portion of the base 10. For example, the cleaner 20 may be moved in a direction toward the wire clamp C. For example, the cleaner 20 may include an actuator and a rod.

In example embodiments of the present inventive concept, the cleaner 20 may selectively enter into a groove of the wire clamp C. The cleaner 20 may clean the wire clamp C by using a cleaning tape T. For example, the cleaner 20 may clean the wire clamp C by using a vibration.

The supplying roller 30 may supply the cleaning tape T to the cleaner 20. The supplying roller 30 may be arranged at one side (e.g., a first side) of the cleaner 20. The cleaning tape T may be wound on the supplying roller 30.

The collecting roller 32 may collect the cleaning tape T from the cleaner 20. For example, the collecting roller 32 may collect the cleaning tape T, which may clean the wire clamp C, from the cleaner 20. Thus, the cleaning tape T cleaning the wire clamp C may be wound on the collecting roller 32. The collecting roller 32 may be arranged at another side (e.g., a second side opposite to the third side) of the cleaner 20. For example, the supplying roller 30 and the collecting roller 32 may be positioned at two sides of the cleaner 20.

The first guide roller 40 may be arranged between the supplying roller 30 and the cleaner 20. The first guide roller 40 may guide a path of the cleaning tape T that is supplied from the supplying roller 30 to the cleaner 20. Further, the first guide roller 40 may push or move the cleaning tape T that is supplied from the supplying roller 30 to the cleaner 20 to apply a tension to the cleaning tape T. Thus, a deflection of the cleaning tape T between the supplying roller 30 and the cleaner 20 may be prevented so that the cleaning tape T may be smoothly supplied to the cleaner 20 from the supplying roller 30.

The second guide roller 42 may be arranged between the collecting roller 32 and the cleaner 20. The second guide roller 42 may guide a path of the cleaning tape T that is collected from the cleaner 20 to the collecting roller 32. Further, the second guide roller 42 may push the cleaning tape T that is collected from the cleaner 20 to the collecting roller 32 to apply a tension to the cleaning tape T. Thus, a deflection of the cleaning tape T between the collecting roller 32 and the cleaner 20 may be prevented so that the cleaning tape T may be smoothly collected to the collecting roller 32 from the cleaner 20.

The wire guide 50 may selectively push a wire W clamped by the wire clamp C before a cleaning process by the cleaner 20. Thus, the wire W pushed by the wire guide 50 may be released from the wire clamp C. In example embodiments of the present inventive concept, the wire guide 50 may be positioned adjacent to the cleaner 20. Further, the wire guide 50 may be moved together with the cleaner 20. For example, the wire guide 50 may include an actuator and a rod.

FIGS. 2 to 4 are plan views illustrating an operation of a wire guide in the cleaning apparatus in FIG. 1.

Referring to FIG. 2, an end of the wire guide 50 may be protruded beyond an end of the cleaner 20 toward the wire clamp C.

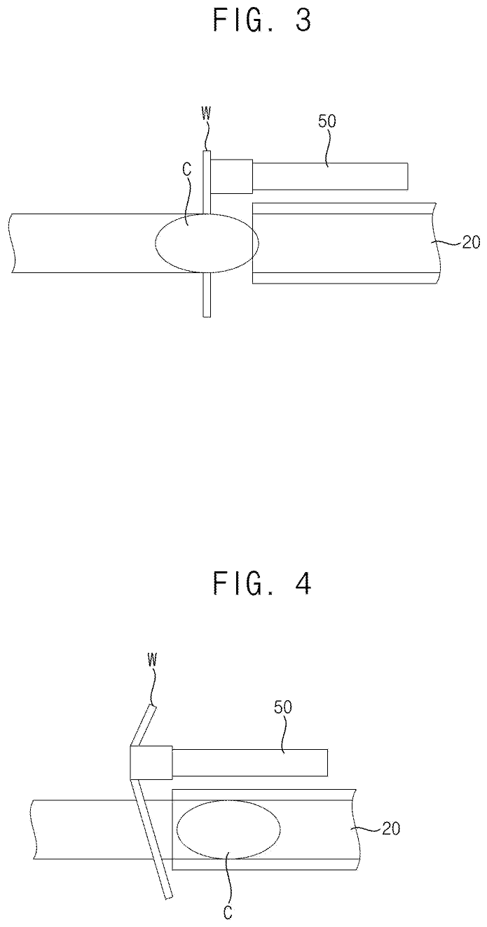

Referring to FIG. 3, before the cleaner 20 may enter into the wire clamp C, the wire guide 50 may make contact with the wire W.

Referring to FIG. 4, the wire guide 50 may be continuously moved forwardly to push the wire W. Thus, the wire W may be released from the wire clamp C. In this state, the cleaner 20 may enter into the wire clamp C to clean the wire clamp C. When the wire guide 50 may be returned to an original position, the released wire W may be returned into the wire clamp C.

Therefore, the wire clamp C may be cleaned under a condition that the wire W might not be removed from the wire clamp C. As a result, a time for cleaning the wire clamp C may be decreased.

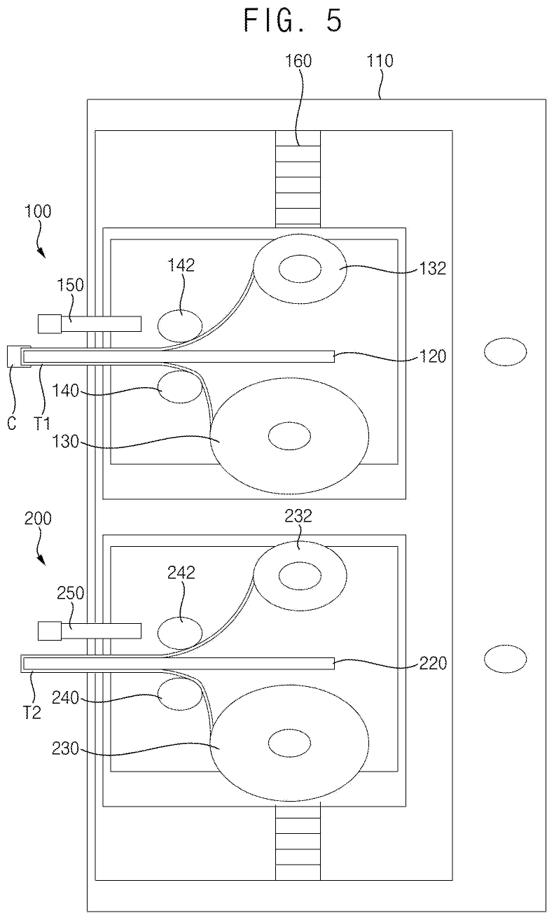

FIG. 5 is a plan view illustrating a cleaning system for a wire clamp in accordance with example embodiments of the present inventive concept.

Referring to FIG. 5, a cleaning system for a wire clamp in accordance with example embodiments of the present inventive concept may include a base 110, a rail 160, a first cleaning apparatus 100 and a second cleaning apparatus 200.

The rail 160 may be arranged at the base 110. For example, the rail 160 may be extended in a direction substantially perpendicular to the movement direction of the cleaner 20 in FIG. 1. For example, the base 110 may support the rail 160.

The first cleaning apparatus 100 may be movably connected to the rail 160. For example, the first cleaning apparatus 100 may be connected to the rail 160 and configured to slide along the rail 160. The first cleaning apparatus 100 may clean the wire clamp C by using a first cleaning tape T1. In example embodiments of the present inventive concept, the first cleaning tape T1 may include an abrasive configured to polish the wire clamp C. For example, the abrasive may include a diamond, but not limited thereto.

The second cleaning apparatus 200 may be movably connected to the rail 160. For example, the second cleaning apparatus 200 may be connected to the rail 160 and configured to slide along the rail 160. The second cleaning apparatus 200 may clean the wire clamp C by using a second cleaning tape T2. In example embodiments of the present inventive concept, the second cleaning tape T2 may include a cleaning paper configured to remove a contaminant that is on the wire clamp C and a contaminant that may be generated in the first cleaning process.

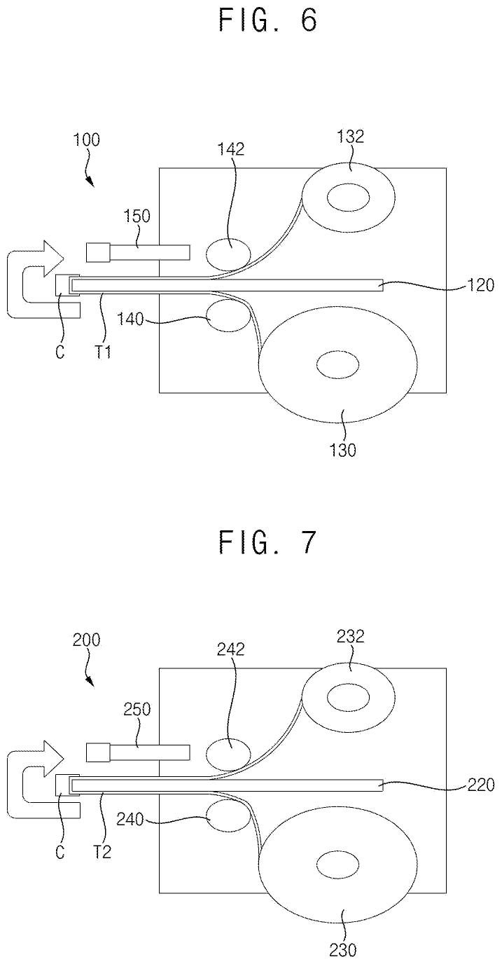

FIG. 6 is a plan view illustrating a first cleaning apparatus of the cleaning system in FIG. 5.

Referring to FIG. 6, the first cleaning apparatus 100 may a first cleaner 120, a first supplying roller 130, a first collecting roller 132, a first guide roller 140, a second guide roller 142 and a first wire guide 150. The first cleaner 120, the first supplying roller 130, the first collecting roller 132, the first guide roller 140, the second guide roller 142 and the first wire guide 150 in FIG. 6 may be substantially the same as the cleaner 20, the supplying roller 30, the collecting roller 32, the first guide roller 40, the second guide roller 42 and the wire guide 50 in FIG. 1, respectively.

For example, the first cleaner 120 may selectively enter into the groove of the wire clamp C. The first cleaner 120 may clean the wire clamp C by using the first cleaning tape T1.

The first supplying roller 130 may supply the first cleaning tape T1 to the first cleaner 120. The first supplying roller 130 may be arranged at one side (e.g., a first side) of the first cleaner 120. The first cleaning tape T1 may be wound on the first supplying roller 130.

The first collecting roller 132 may collect the first cleaning tape T1 from the first cleaner 120. For example, the first collecting roller 132 may collect the first cleaning tape T1, which may clean the wire clamp C, from the first cleaner 120. Thus, the first cleaning tape T1 that cleans the wire clamp C may be wound on the first collecting roller 132. The first collecting roller 132 may be arranged at the other side (e.g., a second side opposite to the first side) of the first cleaner 120. For example, the first supplying roller 130 and the first collecting roller 132 may be positioned at two sides of the first cleaner 120. For example, the first supply roller 130 and the first collecting roller 132 are positioned at opposing sides of the first cleaner 120, respectively.

The first guide roller 140 may be arranged between the first supplying roller 130 and the first cleaner 120. The first guide roller 140 may guide a path of the first cleaning tape T1, which is supplied from the first supplying roller 130, to the first cleaner 120. Further, the first guide roller 140 may push the first cleaning tape T1, which is supplied from the first supplying roller 130, to the first cleaner 120 to apply a tension to the first cleaning tape T1.

The second guide roller 142 may be arranged between the first collecting roller 132 and the first cleaner 120. The second guide roller 142 may guide a path of the first cleaning tape T1, which is collected from the first cleaner 120, to the first collecting roller 132. Further, the second guide roller 142 may push the first cleaning tape T1, which is collected from the first cleaner 120, to the first collecting roller 132 to apply a tension to the first cleaning tape T1.

The first wire guide 150 may selectively push the wire W, which is clamped by the wire clamp C, before a cleaning process by the first cleaner 120. Thus, the wire W that is pushed by the first wire guide 150 may be released from the wire clamp C. In example embodiments of the present inventive concept, the first wire guide 150 may be positioned adjacent to the first cleaner 120. Further, the first wire guide 150 may move with the first cleaner 120.

FIG. 7 is a plan view illustrating a second cleaning apparatus of the cleaning system in FIG. 5.

Referring to FIG. 7, the second cleaning apparatus 200 may a second cleaner 220, a second supplying roller 230, a second collecting roller 232, a first guide roller 240, a second guide roller 242 and a second wire guide 250. The second cleaner 220, the second supplying roller 230, the second collecting roller 232, the first guide roller 240, the second guide roller 242 and the second wire guide 250 in FIG. 7 may be substantially the same as the cleaner 20, the supplying roller 30, the collecting roller 32, the second guide roller 40, the second guide roller 42 and the wire guide 50 in FIG. 1, respectively. For example, the second cleaning apparatus 200 may be substantially the same as the first cleaning apparatus 100.

For example, the second cleaner 220 may selectively enter into the groove of the wire clamp C. The second cleaner 220 may clean the wire clamp C by using the second cleaning tape T2.

The second supplying roller 230 may supply the second cleaning tape T2 to the second cleaner 220. The second supplying roller 230 may be arranged at one side (e.g., a first side) of the second cleaner 220. The second cleaning tape T2 may be wound on the second supplying roller 230.

The second collecting roller 232 may collect the second cleaning tape T2 from the second cleaner 220. For example, the second collecting roller 232 may collect the second cleaning tape T2, which may clean the wire clamp C, from the second cleaner 220. Thus, the second cleaning tape T2, which cleans the wire clamp C, may be wound on the second collecting roller 232. The second collecting roller 232 may be arranged at the other side (e.g., a second side) of the second cleaner 220. For example, the second supplying roller 230 and the second collecting roller 232 may be positioned at two sides of the second cleaner 220. For example, the second supplying roller 230 and the second collecting roller 232 are positioned at opposing sides of the second cleaner 120, respectively.

The first guide roller 240 may be arranged between the second supplying roller 230 and the second cleaner 220. The first guide roller 240 may guide a path of the second cleaning tape T2, which is supplied from the second supplying roller 230, to the second cleaner 220. Further, the first guide roller 240 may push the second cleaning tape T2, which is supplied from the second supplying roller 230, to the second cleaner 220 to apply a tension to the second cleaning tape T2.

The second guide roller 242 may be arranged between the second collecting roller 232 and the second cleaner 220. The second guide roller 242 may guide a path of the second cleaning tape T2, which is collected from the second cleaner 220, to the second collecting roller 232. Further, the second guide roller 242 may push the second cleaning tape T2, which is collected from the second cleaner 220, to the second collecting roller 232 to apply a tension to the second cleaning tape T2.

The second wire guide 250 may selectively push the wire W, which is clamped by the wire clamp C, before a cleaning process by the second cleaner 220. Thus, the wire W, which is pushed by the second wire guide 250, may be released from the wire clamp C. In example embodiments of the present inventive concept, the second wire guide 250 may be positioned adjacent to the second cleaner 220. Further, the second wire guide 250 may move with the second cleaner 220.

FIGS. 8 to 15 are plan views illustrating an operation of the cleaning system in FIG. 5.

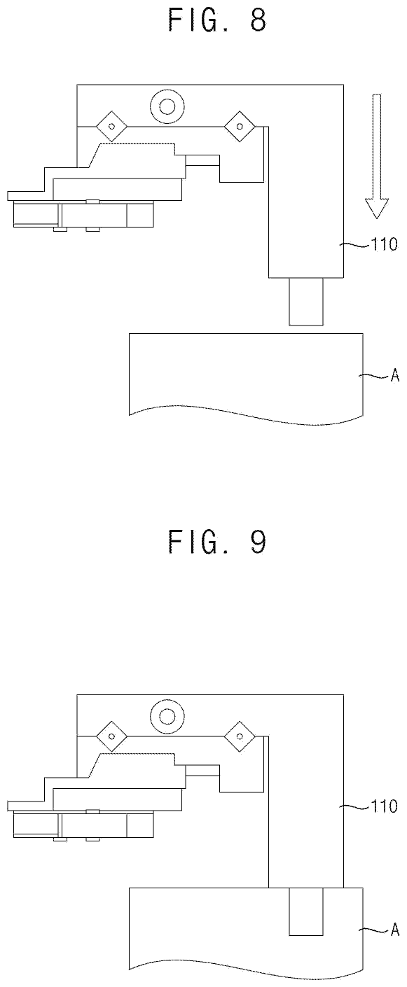

Referring to FIGS. 8 and 9, the base 110 with the first cleaning apparatus 100 and the second cleaning apparatus 200 may be downwardly moved. The base 110 may then be docked with a wire bonding apparatus A.

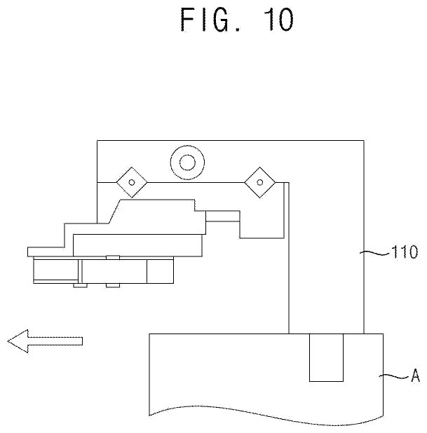

Referring to FIG. 10, the base 110 including the first cleaning apparatus 100 and the second cleaning apparatus 200 may be moved toward the wire clamp C. For example, the first cleaning apparatus 100 and the second cleaning apparatus 200 may be moved toward the wire clamp C.

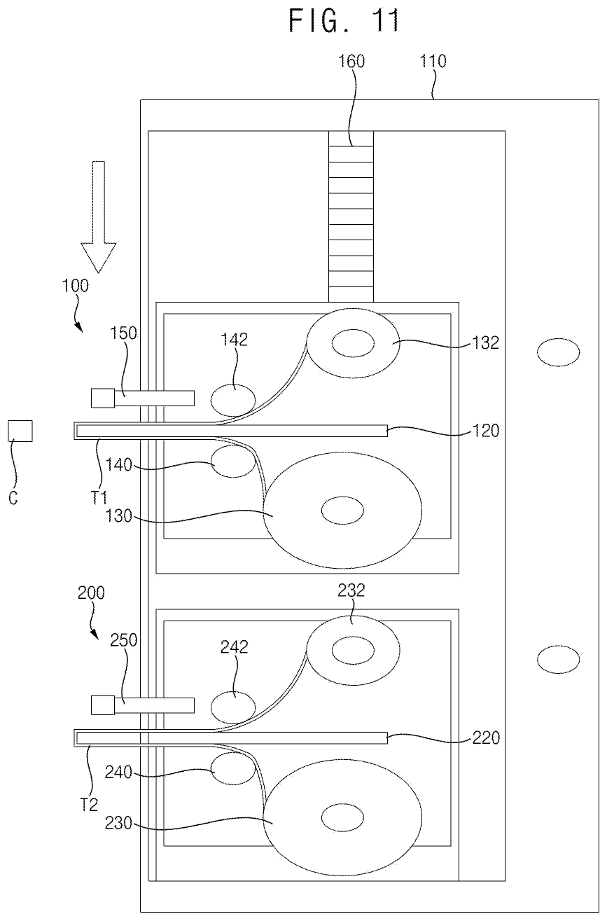

Referring to FIG. 11, the first cleaning apparatus 100 may be moved on the rail 160. For example, the first cleaning apparatus 100 may be positioned adjacent to the wire clamp C. For example, the first cleaning apparatus 100 may be positioned at a front of the wire clamp C.

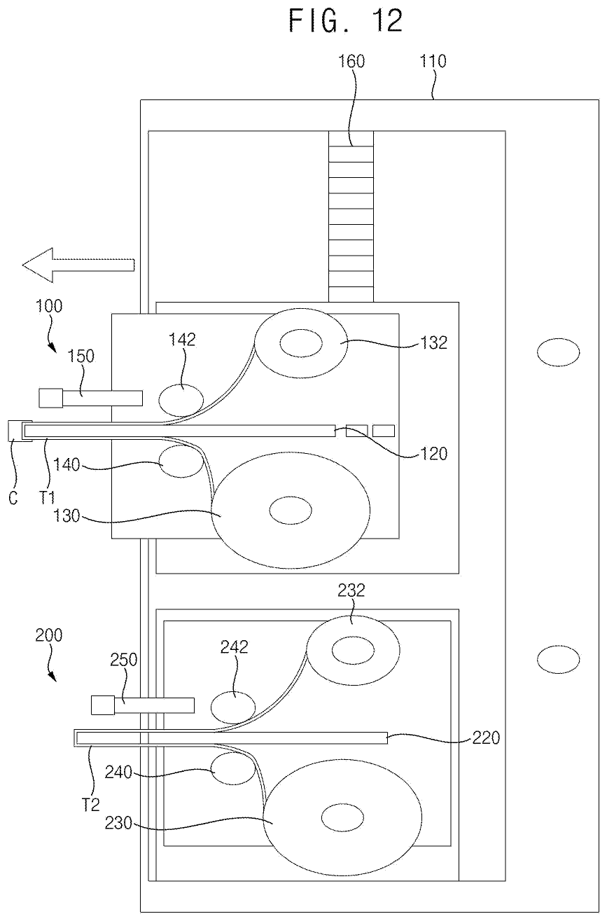

Referring to FIG. 12, the first cleaning apparatus 100 may be moved toward the wire clamp C. The first cleaning apparatus 100 may clean the wire clamp C by using the first cleaning tape T1. For example, the first cleaning apparatus 100 may primarily clean the wire clamp C by using the first cleaning tape T1.

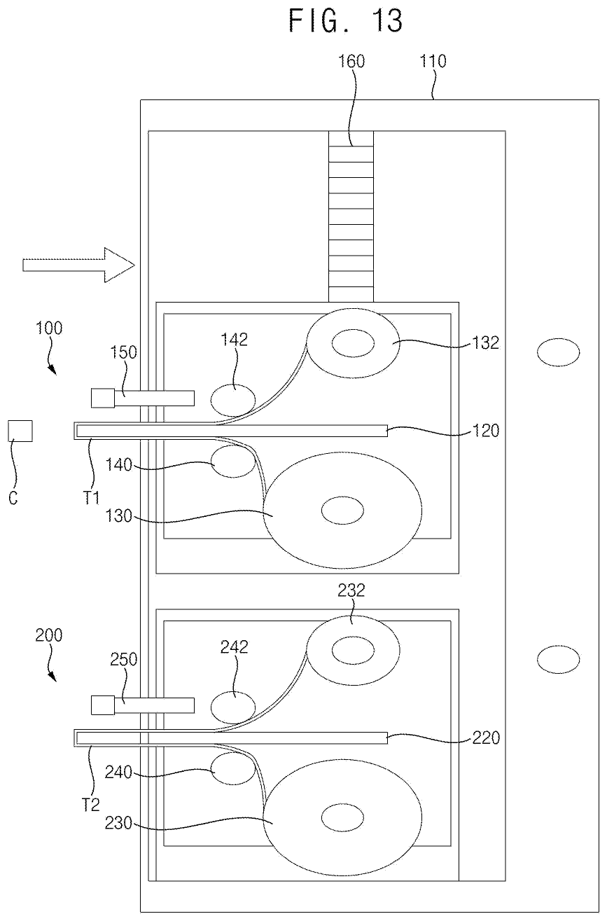

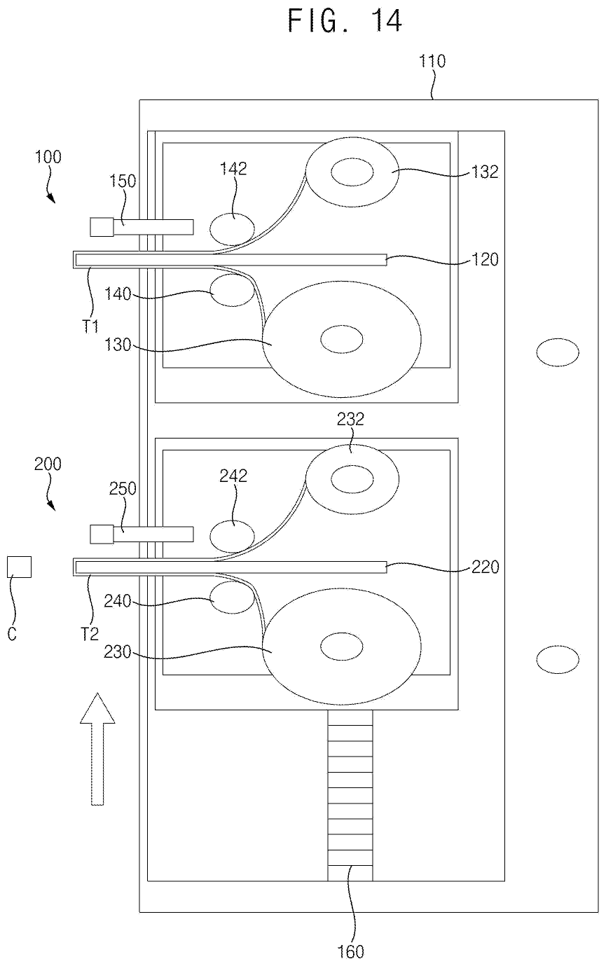

Referring to FIG. 13, after cleaning the wire clamp C, the first cleaning apparatus 100 may be returned to an original position.

Referring to FIG. 14, the second cleaning apparatus 200 may be moved on the rail 160. For example, the second cleaning apparatus 100 may be positioned adjacent to the wire clamp C. For example, the second cleaning apparatus 200 may be positioned at the front of the wire clamp C.

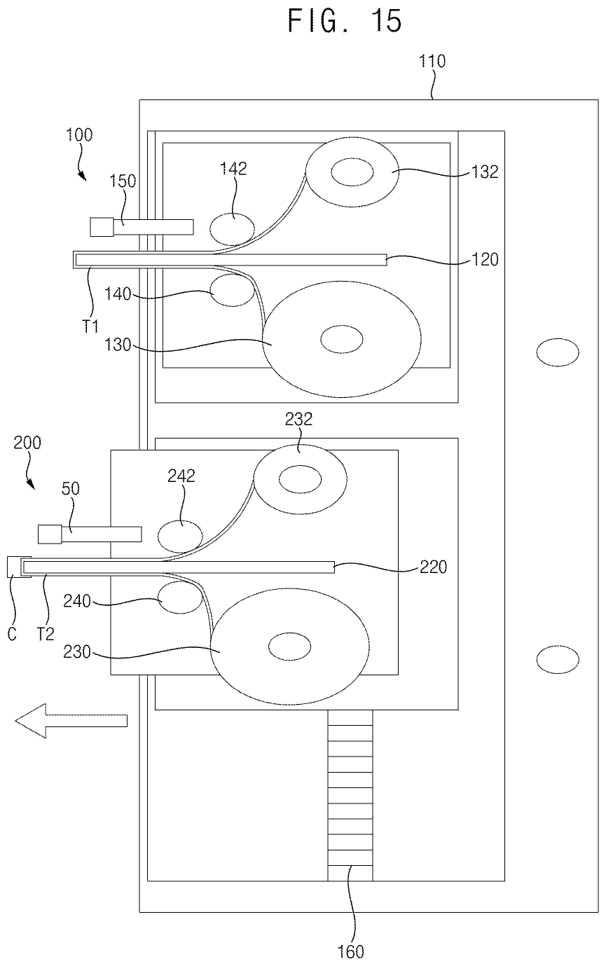

Referring to FIG. 15, the second cleaning apparatus 200 may be moved toward the wire clamp C. The second cleaning apparatus 200 may clean the wire clamp C using the second cleaning tape T2. For example, after the first cleaning apparatus 100 cleans the wire clamp C, the second cleaning apparatus 200 may clean the wire clamp C by using the second cleaning tape T2.

According to example embodiments, the first and second guide rollers may apply the tensions to the cleaning tape so that the cleaning tape may be smoothly supplied to the cleaner from the supplying roller and be smoothly collected from the cleaner to the collecting roller. Thus, cleaning efficiency by using the cleaning tape may be increased. Further, the wire guide may push the wire to release the wire from the wire clamp before cleaning the wire clamp by the cleaner so that the wire clamp may be cleaned without removing the wire from the wire clamp. Thus, a cleaning time of the wire clamp may be decreased.

Furthermore, the first cleaning apparatus may primarily clean the wire clamp by using the first cleaning tape. The second cleaning apparatus may secondarily clean the wire clamp by using the second cleaning tape. Thus, the cleaning efficiency of the wire clamp may be remarkably increased.

The foregoing is illustrative of example embodiments of the present inventive concept and is not to be construed as limiting thereof. Although a few example embodiments have been described, those skilled in the art will readily appreciate that many modifications and various changes in form and details are possible in the example embodiments of the present inventive concept without departing from the spirit and scope of the present inventive concept. Accordingly, all such modifications are intended to be included within the scope of the present inventive concept. In the claims, means-plus-function clauses are intended to cover the structures described herein as performing the recited function and not only structural equivalents but also equivalent structures. Therefore, it is to be understood that the foregoing is illustrative of various example embodiments of the present inventive concept and is not to be construed as limited to the specific example embodiments disclosed herein, and that modifications to the disclosed example embodiments of the present inventive concept, as well as other example embodiments of the present inventive concept, are intended to be included within the scope of the appended claims.

What is claimed is:

1. A cleaning apparatus for a wire clamp, the cleaning apparatus comprising:
a cleaner that cleans the wire clamp that clamps a wire;
a supplying roller that supplies a cleaning tape to the cleaner;
a first guide roller that applies a tension to the cleaning tape that is supplied from the supplying roller to the cleaner;
a collecting roller that collects the cleaning tape, which cleans the wire clamp, from the cleaner; and
a second guide roller that applies a tension to the cleaning tape that is collected from the cleaner by the collecting roller.

2. The cleaning apparatus of claim 1, wherein the supplying roller and the collecting roller are positioned at sides of the cleaner.

3. The cleaning apparatus of claim 2, wherein the first guide roller is positioned between the supplying roller and the cleaner, and the second guide roller is positioned between the collecting roller and the cleaner.

4. The cleaning apparatus of claim 1, further comprising a wire guide that pushes the wire to release the wire from the wire clamp before cleaning the wire clamp with the cleaner.

5. The cleaning apparatus of claim 4, wherein the wire guide is connected to the cleaner to be moved together with the cleaner.

6. A cleaning apparatus for a wire clamp, the cleaning apparatus comprising:
a cleaner configured to clean the wire clamp that clamps a wire;
a supplying roller that supplies a cleaning tape to the cleaner;
a collecting roller that collects the cleaning tape, which cleans the wire clamp, from the cleaner; and
a wire guide that pushes the wire to release the wire from the wire clamp before cleaning the wire clamp with the cleaner.

7. The cleaning apparatus of claim 6, wherein the wire guide is connected to the cleaner and is moved together with the cleaner.

8. A cleaning system for a wire clamp, the cleaning system comprising:
a first cleaning apparatus that cleans the wire clamp, which clamps a wire, by using a first cleaning tape; and
a second cleaning apparatus that cleans the wire clamp by using a second cleaning tape.

9. The cleaning system of claim 8, wherein the first cleaning tape comprises an abrasive.

10. The cleaning system of claim 9, wherein the first cleaning apparatus comprises:
a first cleaner that cleans the wire clamp;
a first supplying roller that supplies the first cleaning tape to the first cleaner;
a first guide roller that applies a tension to the first cleaning tape that is supplied from the first supplying roller to the first cleaner;
a first collecting roller that collects the first cleaning tape, which cleans the wire clamp, from the first cleaner; and
a second guide roller that applies a tension to the first cleaning tape that is collected from the first cleaner by the first collecting roller.

11. The cleaning system of claim 10, wherein the first supplying roller and the first collecting roller are positioned at two sides of the first cleaner.

12. The cleaning system of claim 11, wherein the first guide roller is positioned between the first supplying roller and the first cleaner, and the second guide roller is positioned between the first collecting roller and the first cleaner.

13. The cleaning system of claim 10, wherein the first cleaning apparatus further comprises a first wire guide that pushes the wire to release the wire from the wire clamp before cleaning the wire clamp with the first cleaner.

14. The cleaning system of claim 8, wherein the second cleaning tape comprises a cleaning tape that removes a contaminant from the wire clamp.

15. The cleaning system of claim 9, wherein the second cleaning apparatus comprises:
a second cleaner that cleans the wire clamp;
a second supplying roller that supplies the second cleaning tape to the second cleaner;
a first guide roller that applies a tension to the second cleaning tape that is supplied from the second supplying roller to the second cleaner;
a second collecting roller that collects the second cleaning tape, which cleans the wire clamp, from the second cleaner; and
a second guide roller that applies a tension to the second cleaning tape that is collected from the second cleaner by the second collecting roller.

16. The cleaning system of claim 15, wherein the second supplying roller and the second collecting roller are positioned at two sides of the second cleaner.

17. The cleaning system of claim 16, wherein the first guide roller is positioned between the second supplying roller and the second cleaner, and the second guide roller is positioned between the second collecting roller and the second cleaner.

18. The cleaning system of claim 15, wherein the second cleaning apparatus further comprises a second wire guide that pushes the wire to release the wire from the wire clamp before cleaning the wire clamp with the second cleaner.

19. The cleaning system of claim 8, further comprising a rail that supports the first cleaning apparatus and the second cleaning apparatus, wherein the first cleaning apparatus and the second cleaning apparatus move along the rail.

20. The cleaning system of claim 19, further comprising a base that supports the rail.
